(19) United States
(12) Patent Application Publication
(10) Pub. No.: US 2025/0372547 A1
(43) Pub. Date: Dec. 4, 2025

(54) SEMICONDUCTOR STRUCTURE

(71) Applicant: MEDIATEK INC., Hsinchu City (TW)

(72) Inventors: Sang-Mao CHIU, Hsinchu City (TW); Yi-Chieh LIN, Hsinchu City (TW); Wen-Sung HSU, Hsinchu City (TW); Chi-Yuan CHEN, Hsinchu City (TW); Kai-Cheng WANG, Hsinchu City (TW); Shih-Chin LIN, Hsinchu City (TW); Ya-Jui HSIEH, Hsinchu City (TW)

(21) Appl. No.: 19/220,689

(22) Filed: May 28, 2025

Related U.S. Application Data
(60) Provisional application No. 63/653,359, filed on May 30, 2024.

(51) Int. Cl. H01L 23/64; H01L 23/498

(52) U.S. Cl. CPC H01L 23/642; H01L 23/49822

(57) ABSTRACT

A semiconductor structure is provided. The semiconductor structure includes a substrate. The substrate includes a core, a conductive material, a high-k dielectric material, and a redistribution layer. The core has a first hole, a second hole, and a third hole passing through it. The conductive material disposed in the first hole acts as a first electrode of a capacitor, the conductive material disposed in the second hole acts as a second electrode of the capacitor. The high-k dielectric material is disposed in the third hole and acts as a dielectric material of the capacitor. The dielectric constant of the high-k dielectric material is higher that the dielectric constant of the core. The redistribution layer is disposed on the core and connected to at least one of the conductive material in the first hole and the conductive material in the second hole.

### CROSS REFERENCE TO RELATED APPLICATIONS

This application claims the benefit of U.S. Provisional Application No. 63/653,359, filed on May 30, 2024, the entirety of which is incorporated by reference herein.

### BACKGROUND OF THE DISCLOSURE

### Field of the Disclosure

The present disclosure relates to a semiconductor structure and, in particular, it relates to a package substrate having embedded passive components.

### Description of the Related Art

In order to ensure miniaturization and multi-functionality of electronic products and communication devices, it is desired that semiconductor packages be small in size, support multi-pin connection, operate at high speeds, and have high functionality. Additionally, in a high-frequency application, such as a radio frequency (RF) system in a package (SiP) assembly, one or more integrated passive devices (IPDs) are typically used to perform the functions.

In a conventional SiP assembly, passive devices are often placed on a printed circuit board (PCB) or on a package. However, a PCB is required to provide additional area for the passive devices that are mounted on it. Additionally, the total height of the SiP assembly increases when the passive devices are mounted on the package. As a result, it is difficult to reduce the size of a package assembly.

Thus, a novel semiconductor structure for a package is desirable.

### BRIEF SUMMARY OF THE DISCLOSURE

An embodiment of the present disclosure provides a semiconductor structure. The semiconductor structure includes a substrate. The substrate includes a core, a conductive material, a high-k dielectric material and a redistribution layer. The core has a first hole, a second hole and a third hole passing through it. The conductive material is disposed in the first hole and the second hole. The conductive material disposed in the first hole acts as a first electrode of a capacitor, the conductive material disposed in the second hole acts as a second electrode of the capacitor. The high-k dielectric material is disposed in the third hole and between the first electrode and the second electrode. The high-k dielectric material acts as a dielectric material of the capacitor. The redistribution layer is disposed on the core and connected to at least one of the conductive material in the first hole and the conductive material in the second hole.

An embodiment of the present disclosure provides a semiconductor structure. The semiconductor structure includes a substrate and a capacitor embedded in the substrate. The substrate includes a core, a first insulating layer and a second insulating layer. The core has a first hole, a second hole and a third hole passing through it. The first insulating layer and a second insulating layer are disposed at opposite sides of the core. The capacitor includes a first electrode, a second electrode and a high-k dielectric material. The first electrode is formed by a conductive material disposed in the first hole. The second electrode is formed by the conductive material disposed in the second hole. The high-k dielectric material is disposed at least in the third hole and between the first electrode and the second electrode. The dielectric constant of the high-k dielectric material is between about 10 and 20.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a semiconductor structure in accordance with some embodiments of the disclosure;

FIG. 2 is a schematic top view of a core of the semiconductor structure of FIG. 1 (or FIG. 5) in accordance with some embodiments of the disclosure;

FIG. 3 is a schematic cross-sectional view of a semiconductor structure in accordance with some embodiments of the disclosure;

FIG. 4 is a schematic top view of a core of the semiconductor structure of FIG. 3 (or FIG. 6) in accordance with some embodiments of the disclosure;

FIG. 5 is a schematic cross-sectional view of a semiconductor structure in accordance with some embodiments of the disclosure;

FIG. 6 is a schematic cross-sectional view of a semiconductor structure in accordance with some embodiments of the disclosure;

FIG. 7 is a schematic cross-sectional view of a semiconductor structure in accordance with some embodiments of the disclosure; and

FIG. 8 is a schematic top view of a core of the semiconductor structure of FIG. 7 in accordance with some embodiments of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

In recent years, with the demand for semiconductor package structure toward small area and/or size, high I/O pad-density, increased functionality, low costs, improved electrical performance and reliability, embedded passive component technology for package substrates has been developed rapidly. The conventional package substrates usually use integrated passive devices (IPDs) or multi-layer ceramic capacitors (MLCCs) embedded in the substrate core. However, the conventional package substrates still suffer disadvantages of high fabrication cost and limited capacitance for high-frequency applications. Thus, a cost-effective package substrate having embedded capacitors for semiconductor packages is desirable.

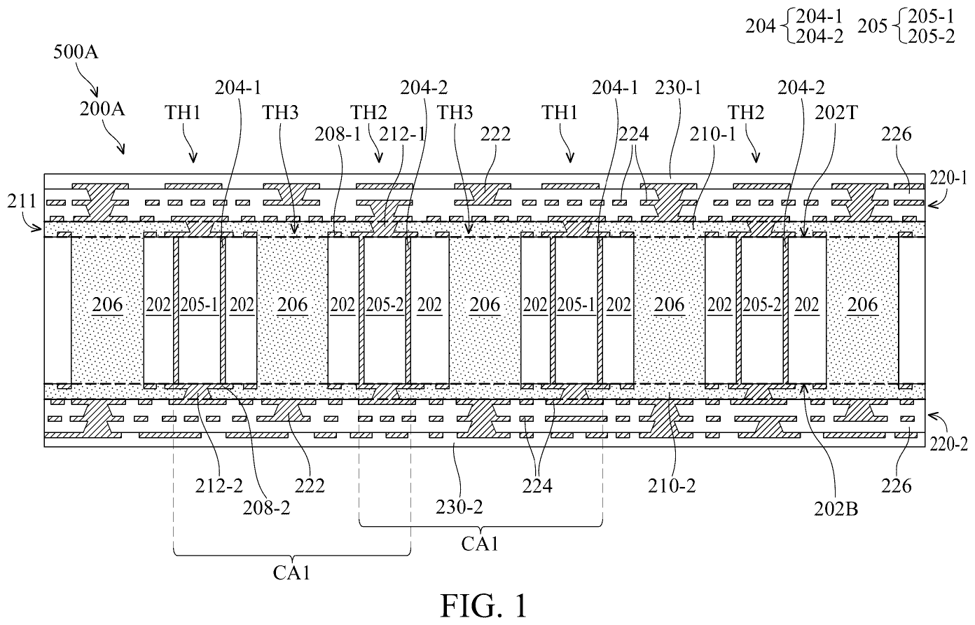

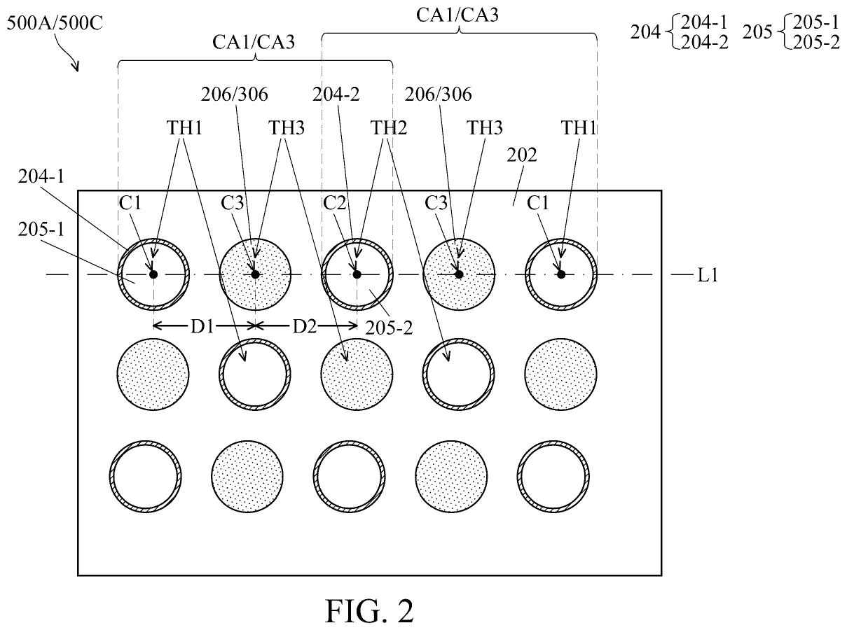

FIG. 1 is a schematic cross-sectional view of a semiconductor structure 500A in accordance with some embodiments of the disclosure. FIG. 2 is a schematic top view of a core 202 of the semiconductor structure 500A of FIG. 1 in accordance with some embodiments of the disclosure, showing the arrangements of electrodes and dielectric material of a capacitor embedded in a substrate.

The semiconductor structure 500A includes a substrate 200A. For example, the substrate 200A may include a multi-layered package substrate. The substrate 200A may provide mechanical support and electrical connections between integrated circuit (IC) chips and conductive bumps attached to the top and bottom surfaces of the substrate 200A. The substrate 200A may have various types including, for example, cored substrates, including thin core, thick core (e.g., laminate BT (bismaleimide-triazine resin) or FR-4 type fibrous board material), and laminate core. Alternatively, the cored package substrates, for example, can be built up layer by layer, with layers of conductive material (usually copper) separated by layers of insulating dielectric, with interlayer connections being formed with through holes or vias (microvias).

In some embodiments, the substrate 200A includes the core 202, a conductive material 204, a high-k dielectric material 206 and redistribution layers 220-1 and 220-2.

As shown in FIG. 1, the core 202 has a top surface 202T and a bottom surface 202B. In some embodiments, the core 202 may be formed of polypropylene (PP), Pre-preg, FR-4 and/or other epoxy laminate material.

As shown in FIG. 1, the core 202 has holes TH1, TH2 and TH3 embedded and passing through it. In some embodiments, the holes TH1, TH2 and TH3 may be arranged repeatedly in a specific order. For example, the holes TH1, TH2 and TH3 may be arranged as an array passing through the core 202, as shown in FIG. 2. The hole TH3 may be disposed between the one hole TH1 and the one hole TH2 in row and/or column direction(s). In other words, the hole TH1 is disposed between two holes TH3 in row and/or column direction(s). In addition, the hole TH2 is disposed between two holes TH3 in row and/or column direction(s).

In some embodiments, each of the holes TH3 may be located on the line (e.g., a line L1) connecting the center point C1 of the adjacent hole TH1 with the center point C2 of the adjacent hole TH2. In some embodiments, each of the holes TH3 may be located at the midpoint between the adjacent holes TH1 and TH2. For example, the center point C3 of the hole TH3 may be substantially located at the midpoint between the adjacent holes TH1 and TH2. In some embodiments, the distance D1 between the hole TH3 to the adjacent hole TH1 may be equal to or not equal to the distance D2 between the hole TH3 to the adjacent hole TH2. In some embodiments, the holes TH1, TH2 and TH3 may be formed by a drilling process.

The conductive material 204 (including conductive material portions 204-1, 204-2) is disposed in the hole TH1 and the hole TH2. In some embodiments as shown in FIGS. 1 and 2, each of the conductive material portions 204-1, 204-2 may be formed as a thin conductive layer lining inner walls of the hole TH1 and the hole TH2. The conductive material 204 in the hole TH1 (e.g., the conductive material portion 204-1) and the conductive material 204 in the hole TH2 (e.g., the conductive material portion 204-2) may have a hollow pillar shape. Two terminals (not shown) of the conductive material 204 in each of the holes TH1 and TH2 may be close to the top surface 202T and the bottom surface 202B of the core 202, respectively. In some embodiments, the conductive material 204 includes copper or nickel-copper.

As shown in FIGS. 1 and 2, the semiconductor structure 500A further includes a non-conductive material 205 (including non-conductive material portions 205-1, 205-2) filling the remaining spaces of the holes TH1 and TH2 and surrounded by the conductive material 204. For example, the non-conductive material portion 205-1 may fill the hole TH1 and be surrounded by the conductive material portion 204-1. In addition, the non-conductive material portion 205-2 may fill the hole TH2 and be surrounded by the conductive material portion 204-2. In some embodiments, the non-conductive material 205 includes an ink.

The high-k dielectric material 206 is disposed in the hole TH3. As shown in FIGS. 1 and 2, the high-k dielectric material 206 may fill the hole TH3. In addition, the high-k dielectric material 206 may be in contact with an inner wall of the hole TH3. That is to say, the high-k dielectric material 206 may be in contact with the core 202. Furthermore, the high-k dielectric material 206 is separated from the conductive material 204 in the holes TH1 and TH2 by the core 202.

In some embodiments, the dielectric constant of the high-k dielectric material 206 may be higher than the dielectric constant of the core 202. For example, the dielectric constant of the high-k dielectric material 206 is between about 10 and 20. In this embodiment, the high-k dielectric material 206 includes Ajinomoto Build-Up Film (ABF). In this embodiment, the high-k dielectric material 206 may be formed by coating or lamination.

As shown in FIG. 1, the semiconductor structure 500A further includes conductive layers 208-1 and 208-2 formed directly on the top surface 202T and the bottom surface 202B of the core 202, respectively. In some embodiments, the conductive layers 208-1 and 208-2 may cover the holes TH1 and TH2, the conductive material 204 lining the inner walls of the holes TH1 and TH2 and the non-conductive material 205 filling the holes TH1 and TH2. For example, the conductive layers 208-1 and 208-2 may fully cover or partially cover the holes TH1 and TH2 and the conductive material 204 and the non-conductive material 205 in the holes TH1 and TH2. In addition, the conductive layers 208-1 and 208-2 may be connected (coupled) to the conductive material 204 lining the inner wall walls of the holes TH1 and TH2.

As shown in FIG. 1, the conductive layers 208-1 and 208-2 may partially cover the top surface 202T and the bottom surface 202B of the core 202. In some embodiments, the top and bottom of the high-k dielectric material 206 are not covered by the conductive layers 208-1 and 208-2.

In some embodiments, each of the conductive layers 208-1 and 208-2 may include a set of conductive traces or conductive planes. In some embodiments, the conductive layers 208-1 and 208-2 include a conductive material, such as metals comprising copper, gold, silver, or other applicable metals. For example, the conductive layers 208-1 and 208-2 may be copper layers 208-1 and 208-2.

As shown in FIG. 1, the semiconductor structure 500A further includes insulating layers 210-1 and 210-2 formed on the top surface 202T and the bottom surface 202B of the core 202, respectively. In addition, the insulating layers 210-1 and 210-2 may be disposed on the conductive layers 208-1 and 208-2, respectively. In addition, the insulating layer 210-1 (or 210-2) may cover the conductive layer 208-1 (or 208-2), the holes TH1 and TH2, the conductive material 204 lining the inner walls of the holes TH1 and TH2 and the non-conductive material 205 filling the holes TH1 and TH2.

In some embodiments, the insulating layers 210-1 and 210-2 and the high-k dielectric material 206 are formed of the same material (e.g., a high-k dielectric material having a dielectric constant of between about 10 and 20). In some embodiments, the high-k dielectric material 206 and the insulating layers 210-1 and 210-2 may be formed simultaneously using the same process. In other words, the high-k dielectric material 206 and the insulating layers 210-1 and 210-2 are formed as a high-k dielectric integrated structure 211. The high-k dielectric material 206 and the insulating layers 210-1 and 210-2 are different portions of the high-k dielectric integrated structure 211. There is no interface between the high-k dielectric material 206 and the insulating layers 210-1 and 210-2. As shown in FIG. 1, the high-k dielectric integrated structure 211 may pass through the hole TH3 and extend to cover top surface 202T and the bottom surface 202B of the core 202. In this embodiment, the high-k dielectric integrated structure 211 (including the high-k dielectric material 206 and the insulating layers 210-1 and 210-2) includes a high-k dielectric material suitable formed by coating or lamination, such as Ajinomoto Build-Up Film (ABF).

As shown in FIG. 1, the semiconductor structure 500A further includes vias 212-1, 212-2 disposed in the insulating layers 210-1 and 210-2. The vias 212-1, 212-2 may be formed passing through the insulating layers 210-1 and 210-2 to be coupled to the conductive layers 208-1 and 208-2. For example, the vias 212-1 passing through the insulating layer 210-1 are coupled to portions of the conductive layer 208-1 directly on the holes TH1, TH2. Similarly, the vias 212-2 passing through the insulating layer 210-2 are coupled to portions of the conductive layer 208-2 directly on the holes TH1, TH2. The vias 212-1, 212-2 may be located directly on the non-conductive material 205 filling the holes TH1 and TH2. In addition, the vias 212-1, 212-2 may be formed without overlapping the high-k dielectric material 206 in the hole TH3. In some embodiments, the vias 212-1, 212-2 may be formed by drilling.

The redistribution layers (RDLs) 220-1 and 220-2 are disposed on the insulating layers 210-1 and 210-2, respectively. In some embodiments, each of the redistribution layers 220-1 and 220-2 includes one or more conductive traces 224, one or more vias 222 disposed in one or more insulating layers 226. It should be noted that the number of vias 222, the number of conductive traces 224 and the number of insulating layers 226 shown in FIG. 1 are only an example and is not a limitation to the present disclosure.

In some embodiments, the redistribution layers 220-1 and 220-2 are connected to (or coupled to) the conductive material 204 in the holes TH1 and TH2. More specifically, the conductive material 204 in the holes TH1 and TH2 may be connected to the conductive layers 208-1 and 208-2. The conductive layers 208-1 and 208-2 may be connected to the corresponding vias 212-1 and 212-2 in the insulating layers 210-1 and 210-2. The vias 212-1 and 212-2 located in the insulating layers 210-1 and 210-2 may be connected to vias or traces in the redistribution layers 220-1 and 220-2. For example, each of the conductive layer 208-1 and 208-2 include at least one of a first conductive plane or conductive trace connected to the conductive material 204-1 in the hole TH1 and the redistribution layer 220-1 and a second conductive plane or conductive trace connected to the conductive material 204-2 in the hole TH2 and the redistribution layer 220-2. In one embodiment, the conductive layer 208-1 includes a first conductive plane or conductive trace connected to the conductive material 204-1 in the hole TH1 and the redistribution layer 220-1 and a second conductive plane or conductive trace connected to the conductive material 204-2 in the hole TH2 and the redistribution layer 220-2. In one embodiment, the conductive layer 208-1 includes a first conductive plane or conductive trace connected to the conductive material 204-1 in the hole TH1 and the redistribution layer 220-1, and the conductive layer 208-2 includes a second conductive plane or conductive trace connected to the conductive material 204-2 in the hole TH2 and the redistribution layer 220-2.

In some embodiments, the vias 222 and the conductive traces 224 include a conductive material, such as metals comprising copper, gold, silver, or other applicable metals. In some embodiments, the insulating layers 226 in the redistribution layers 220-1 and 220-2 include a low-k dielectric material. The dielectric constant of the insulating layers 226 may be between about 3 and 4, which is less than the dielectric constant of the high-k dielectric material 206.

As shown in FIG. 1, the semiconductor structure 500A further includes solder mask layers 230-1 and 230-2 disposed over the corresponding redistribution layers 220-1 and 220-2. In some embodiments, the solder mask layers 230-1 and 230-2 may cover the conductive traces 224 on the outermost insulating layers 226 of the redistribution layers 220-1 and 220-2. In addition, the solder mask layers 230-1 and 230-2 may have openings (not shown) to expose corresponding conductive pads (not shown). In some embodiments, the solder mask layers 230-1 and 230-2 may include an epoxy resin.

In the semiconductor structure 500A, the conductive material 204 in the hole TH1 and the hole TH2, and the high-k dielectric material 206 in the hole TH3 between the holes TH1 and TH2 may form a capacitor CA1 embedded in the substrate 200A. Therefore, the semiconductor structure 500A has a plurality of capacitors CA1 formed embedded in the substrate 200A. In each of the capacitors CA1, the conductive material portion 204-1 lining the inner wall of the hole TH1 may serve as a first electrode 204-1 of the capacitor CA1, and the conductive material portion 204-2 lining the inner wall of the hole TH2 may serve as a second electrode 204-2 of the capacitor CA1. The high-k dielectric material 206 disposed in the hole TH3 and a portion of core 202 located between the first electrode 204-1 and the second electrode 204-2 may serve as a dielectric material of the capacitor CA1. In some embodiments, the first electrode 204-1 (or the second electrode 204-2) is commonly used by the adjacent two capacitors CA1.

In some embodiments, the conductive material portions 204-1 lining the inner wall walls of the different holes TH1 are connected (coupled) each other by the vias 212-1 in the insulating layer 210-1 and/or the vias 212-2 in the insulating layer 210-2. In addition, the conductive material portions 204-2 lining the inner wall walls of the different holes TH2 are connected each other by the vias 212-1 in the insulating layer 210-1 and/or the vias 212-2 in the insulating layer 210-2. In some embodiments, the vias 212-1 and/or the vias 212-2 connected (coupled) to the first electrodes 204-1 (the conductive material portions 204-1) are separated from the vias 212-1 and/or the vias 212-2 connected (coupled) to the second electrodes 204-2 (the conductive material portions 204-2). That is, there is no electrical connection between the vias 212-1 and/or the vias 212-2 connected (coupled) to the first electrodes 204-1 (the conductive material portions 204-1) and vias 212-1 and/or the vias 212-2 connected (coupled) to the second electrodes 204-2 (the conductive material portions 204-2).

In some embodiments, the conductive material portion 204-1 lining the inner wall walls of the different holes TH1 are connected (coupled) each other by the vias 212-1 in the insulating layer 210-1 and the vias 222 and the conductive traces 224 in the redistribution layer 220-1, and/or the vias 212-2 in the insulating layer 210-2 and the vias 222 and the conductive traces 224 in the redistribution layer 220-2. In addition, the conductive material portions 204-2 lining the inner wall walls of the different holes TH2 are connected each other by the vias 212-1 in the insulating layer 210-1 and the vias 222 and the conductive traces 224 in the redistribution layer 220-1, and/or the vias 212-2 in the insulating layer 210-2 and the vias 222 and the conductive traces 224 in the redistribution layer 220-2.

In other words, the vias 212-1 in the insulating layer 210-1 and/or the vias 212-2 in the insulating layer 210-2 connected to the conductive material portion 204-1 in one hole TH1 may be connected to the conductive material portion 204-1 in another hole TH1 by the vias 222 and the conductive traces 224 in the redistribution layer 220-1 and/or the vias 222 and the conductive traces 224 in the redistribution layer 220-2. In addition, the vias 212-1 in the insulating layer 210-1 and/or the vias 212-2 in the insulating layer 210-2 connected to the conductive material portion 204-1 in one hole TH2 may be connected to the conductive material portion 204-1 in another hole TH2 by the vias 222 and the conductive traces 224 in the redistribution layer 220-1 and/or the vias 222 and the conductive traces 224 in the redistribution layer 220-2. In some embodiments, the vias 222 and the conductive traces 224 in the redistribution layer 220-1 and/or the redistribution layer 220-2 connected (coupled) to the first electrodes 204-1 (the conductive material portions 204-1) in the various holes TH1 are separated from the vias 222 and the conductive traces 224 in the redistribution layer 220-1 and/or the redistribution layer 220-2 connected (coupled) to the second electrodes 204-2 (the conductive material portions 204-2) in the various holes TH2. That is, there is no electrical connection between the vias 222 and the conductive traces 224 in the redistribution layer 220-1 and/or the redistribution layer 220-2 connected (coupled) to the first electrodes 204-1 (the conductive material portions 204-1) in the various holes TH1 and the vias 222 and the conductive traces 224 in the redistribution layer 220-1 and/or the redistribution layer 220-2 connected (coupled) to the second electrodes 204-2 (the conductive material portions 204-2) in the various holes TH2.

According to the connections of the first electrodes 204-1 (the conductive material portions 204-1) and the connections of the second electrodes 204-2 (the conductive material portions 204-2), the capacitors CA1 formed in the same substrate 200A are connected in parallel. The semiconductor structure 500A may have a large capacitance.

In the semiconductor structure 500A, the capacitors CA1 may be formed inside the substrate 200A using the processes for forming the substrate 200A. The capacitors CA1 may be formed integrated with the substrate 200A of the semiconductor structure 500A. The fabrication cost can be further reduced. The semiconductor structure 500A may use the thin conductive layer (i.e., the conductive material portions 204-1 and 204-2) lining the holes TH1 and TH2 passing through the core 202 as the electrode plates (the first electrode 204-1 and the second electrode 204-2) of each of the capacitors CA1. In addition, the semiconductor structure 500A may use the high-k dielectric material 206 (the dielectric constant of the high-k dielectric material 206 is between about 10 and 20, such as ABF) originally for the build-up layer to fill the hole TH3 between the holes TH1 and TH2 as the dielectric material of the each of the capacitors CA1. The first electrode 204-1 and the second electrode 204-2 of capacitors CA1 may be formed passing through the core 202 in a direction that is vertical to the top surface 202T and the bottom surface 202B of the core 202. The capacitance of each of the capacitors CA1 can be increased. Furthermore, the capacitors CA1 formed in the same substrate 200A may be in a parallel connection to further increase the total capacitance. The semiconductor structure 500A integrating the package substrate (the substrate 200A) and large capacitance embedded capacitors CA1 are cost-effective and suitable for high-frequency applications.

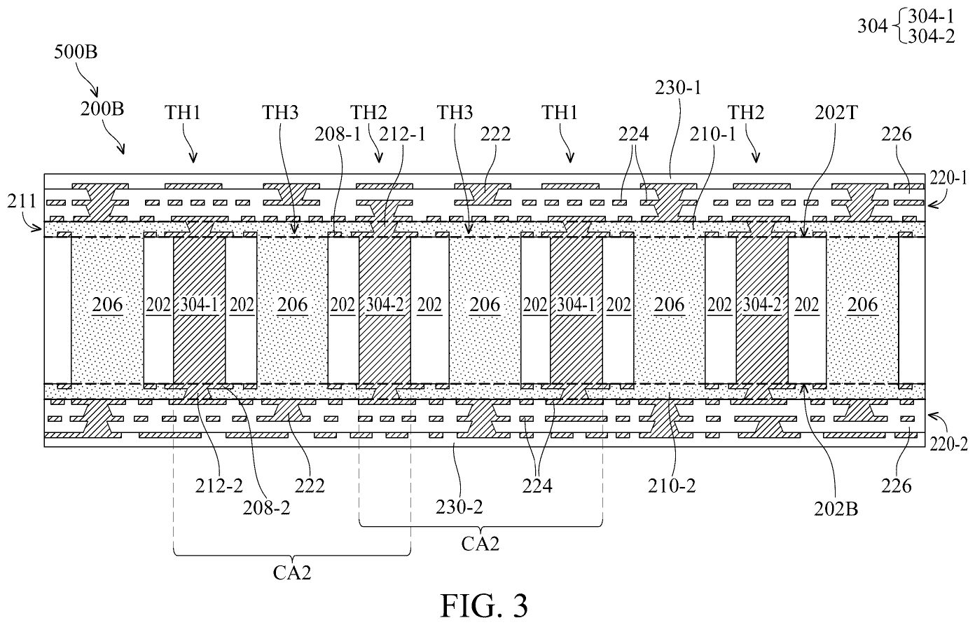

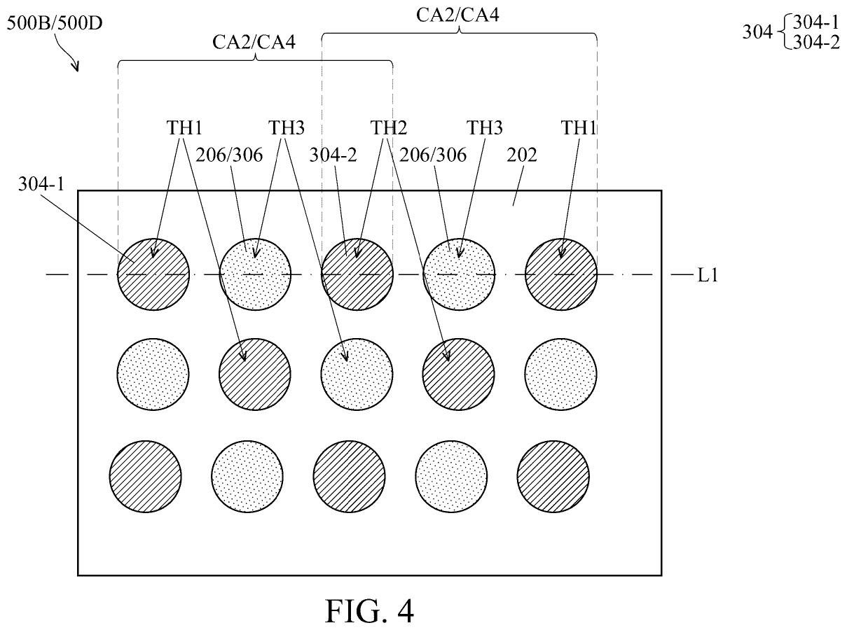

FIG. 3 is a schematic cross-sectional view of a semiconductor structure 500B in accordance with some embodiments of the disclosure. FIG. 4 is a schematic top view of the semiconductor structure 500B of FIG. 3 in accordance with some embodiments of the disclosure, showing the arrangements of electrodes and dielectric material of a capacitor embedded in a substrate. Elements of the embodiments hereinafter, that are the same or similar as those previously described with reference to FIGS. 1 and 2, are not repeated for brevity. As shown in FIGS. 1 to 4, the difference between the semiconductor structure 500A and the semiconductor structure 500B at least includes that a substrate 200B of the semiconductor structure 500B includes a conductive material 304 (including conductive material portions 304-1, 304-2) formed as a conductive pillar filled in the holes TH1 and TH2.

The conductive material 304 in the hole TH1 (e.g., the conductive material portion 304-1) and the conductive material 304 in the hole TH2 (e.g., the conductive material portion 304-2) may have a pillar shape. The conductive material portions 304-1, 304-2 may serve as conductive pillars 304-1, 304-2. Two terminals (not shown) of the conductive material 304 in each of the holes TH1 and TH2 may be close to the top surface 202T and the bottom surface 202B of the core 202, respectively. In addition, the two terminals of the conductive material 304 in each of the holes TH1 and TH2 may be exposed from the top surface 202T and the bottom surface 202B of the core 202, respectively.

In the semiconductor structure 500B, the conductive material 304 filling in the hole TH1 and the hole TH2, and the high-k dielectric material 206 in the hole TH3 may form a capacitor CA2 embedded in the substrate 200B. Therefore, the semiconductor structure 500B has a plurality of capacitors CA2 formed embedded in the substrate 200B. In each of the capacitors CA2, the conductive material portion 304-1 filling the hole TH1 may serve as a first electrode 304-1 of the capacitor CA2, and the conductive material portion 304-2 filling the hole TH2 may serve as a second electrode 304-2 of the capacitor CA2. The high-k dielectric material 206 disposed in the hole TH3 and a portion of core 202 located between the first electrode 304-1 and the second electrode 304-2 may serve as a dielectric material of the capacitor CA2. In some embodiments, the first electrode 304-1 (or the second electrode 304-2) is commonly used by the adjacent two capacitors CA2.

In some embodiments, the conductive material portions 304-1 filling the different holes TH1 are connected (coupled) each other by the vias 212-1 in the insulating layer 210-1 and/or the vias 212-2 in the insulating layer 210-2. In addition, the conductive material portions 304-2 filling the different holes TH2 are connected each other by the vias 212-1 in the insulating layer 210-1 and/or the vias 212-2 in the insulating layer 210-2. There is no electrical connection between the vias 212-1 and/or the vias 212-2 connected (coupled) to the first electrodes 304-1 (the conductive material portions 204-1) and vias 212-1 and/or the vias 212-2 connected (coupled) to the second electrodes 204-2 (the conductive material portions 304-2).

In some embodiments, the conductive material portions 304-1 filling the different holes TH1 are connected (coupled) each other by the vias 212-1 in the insulating layer 210-1 and the vias 222 and the conductive traces 224 in the redistribution layer 220-1, and/or the vias 212-2 in the insulating layer 210-2 and the vias 222 and the conductive traces 224 in the redistribution layer 220-2. In addition, the conductive material portions 304-2 filling the different holes TH2 are connected each other by the vias 212-1 in the insulating layer 210-1 and the vias 222 and the conductive traces 224 in the redistribution layer 220-1, and/or the vias 212-2 in the insulating layer 210-2 and the vias 222 and the conductive traces 224 in the redistribution layer 220-2.

In other words, the vias 212-1 in the insulating layer 210-1 and/or the vias 212-2 in the insulating layer 210-2 connected to the conductive material portion 304-1 in one hole TH1 may be connected to the conductive material portion 304-1 in another hole TH1 by the vias 222 and the conductive traces 224 in the redistribution layer 220-1 and/or the vias 222 and the conductive traces 224 in the redistribution layer 220-2. In addition, the vias 212-1 in the insulating layer 210-1 and/or the vias 212-2 in the insulating layer 210-2 connected to the conductive material portion 304-2 in one hole TH2 may be connected to the conductive material portion 304-2 in another hole TH2 by the vias 222 and the conductive traces 224 in the redistribution layer 220-1 and/or the vias 222 and the conductive traces 224 in the redistribution layer 220-2. There is no electrical connection between the vias 222 and the conductive traces 224 in the redistribution layer 220-1 and/or the redistribution layer 220-2 connected (coupled) to the first electrodes 304-1 (the conductive material portions 304-1) in the various holes TH1 and the vias 222 and the conductive traces 224 in the redistribution layer 220-1 and/or the redistribution layer 220-2 connected (coupled) to the second electrodes 304-2 (the conductive material portions 304-2) in the various holes TH2.

According to the connections of the first electrodes 304-1 (the conductive material portions 304-1) and the connections of the second electrodes 304-2 (the conductive material portions 304-2), the capacitors CA2 formed in the same substrate 200B are connected in parallel. The semiconductor structure 500B may have a large capacitance.

In the semiconductor structure 500B, the capacitors CA2 may be formed inside the substrate 200B using the processes for forming the substrate 200B. The capacitor CA2 may be formed integrated with the substrate 200B of the semiconductor structure 500B. The fabrication cost can be further reduced. The semiconductor structure 500B may use the conductive pillars (i.e., the conductive material portions 304-1, 304-2) filling the holes TH1 and TH2 as the electrodes of each of the capacitor CA2. In addition, the semiconductor structure 500B may use the high-k dielectric material 206 (the dielectric constant of the high-k dielectric material 206 is between about 10 and 20, such as ABF) originally for the build-up layer to fill the hole TH3 between the holes TH1 and TH2 as the dielectric material of the each of the capacitors CA2. The first electrode 304-1 and the second electrode 304-2 of capacitors CA2 may be formed passing through the core 202 in a direction that is vertical to the top surface 202T and the bottom surface 202B of the core 202. The capacitance of each of the capacitors CA2 can be increased. Furthermore, the capacitors CA2 formed in the same substrate 200B may be in a parallel connection to further increase the total capacitance. The semiconductor structure 500B integrating the package substrate (the substrate 200B) and large capacitance embedded capacitors CA2 are cost-effective and suitable for high-frequency applications.

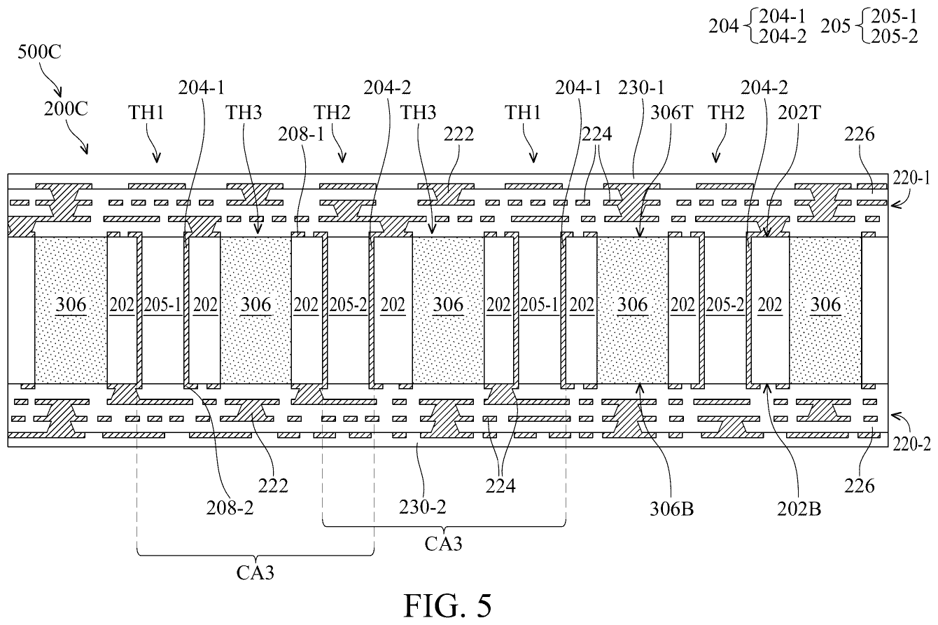

FIG. 5 is a schematic cross-sectional view of a semiconductor structure 500C in accordance with some embodiments of the disclosure. FIG. 2 is also a schematic top view of the semiconductor structure 500C of FIG. 5 in accordance with some embodiments of the disclosure, showing the arrangements of electrodes and dielectric material of a capacitor embedded in a substrate. Elements of the embodiments hereinafter, that are the same or similar as those previously described with reference to FIGS. 1 to 4, are not repeated for brevity.

The semiconductor structure 500C includes a substrate 200C. In some embodiments, the substrate 200C includes the core 202, the conductive material 204, a high-k dielectric material 306, the conductive layers 208-1 and 208-2, the redistribution layers 220-1 and 220-2, and the solder mask layers 230-1 and 230-2.

The high-k dielectric material 306 is disposed in the hole TH3 of the core 202. A top surface 306T and a bottom surface 306B of the high-k dielectric material 306 may align with the top surface 202T and the bottom surface 202B of the core 202, respectively. In other words, the high-k dielectric material 306 is formed without extending to cover the top surface 202T and the bottom surface 202B of the core 202.

The high-k dielectric material 306 may fill the hole TH3. In addition, the high-k dielectric material 306 may be in contact with an inner wall of the hole TH3. That is to say, the high-k dielectric material 306 may be in contact with the core 202. Furthermore, the high-k dielectric material 306 is separated from the conductive material 204 in the holes TH1 and TH2 by the core 202.

In some embodiments, the dielectric constant of the high-k dielectric material 306 may be higher than the dielectric constant of the core 202. For example, the dielectric constant of the high-k dielectric material 306 is between about 10 and 20. In this embodiment, the high-k dielectric material 306 includes ceramic. In this embodiment, the high-k dielectric material 306 may be formed by lamination, hot pressing, degreasing, and sintering.

As shown in FIG. 5, the conductive layers 208-1 and 208-2 of the semiconductor structure 500C are formed on the top surface 202T and the bottom surface 202B of the core 202, respectively. In some embodiments, the conductive layers 208-1 and 208-2 may be connected (coupled) to the conductive material 204 lining inner walls of the holes TH1 and TH2. The conductive layers 208-1 and 208-2 may partially overlap the holes TH1 and TH2.

As shown in FIG. 5, the conductive layers 208-1 and 208-2 may partially cover the top surface 202T and the bottom surface 202B of the core 202. In some embodiments, the top surface 306T and the bottom surface 306B of the high-k dielectric material 306 are not covered by the conductive layers 208-1 and 208-2.

As shown in FIG. 5, the redistribution layers 220-1 and 220-2 of the semiconductor structure 500C are formed directly on the top surface 202T and the bottom surface 202B of the core 202, respectively. In addition, the redistribution layers 220-1 and 220-2 may be disposed on the conductive layers 208-1 and 208-2, respectively. In addition, the redistribution layers 220-1 and 220-2 may cover the conductive layers 208-1 and 208-2, the holes TH1 and TH2, the conductive material 204 lining inner walls of the holes TH1 and TH2 and the non-conductive material 205 filling the holes TH1 and TH2.

In some embodiments, each of the redistribution layers 220-1 and 220-2 includes one or more conductive traces 224, one or more vias 222 disposed in one or more insulating layers 226. The innermost conductive traces 224 or vias 222 (located close to the top surface 202T and the bottom surface 202B of the core 202) of the redistribution layers 220-1 and 220-2 may be directly connected to the conductive layers 208-1 and 208-2. The innermost insulating layers 226 (located close to the top surface 202T and the bottom surface 202B of the core 202) of the redistribution layers 220-1 and 220-2 may directly cover the conductive layers 208-1 and 208-2 without other insulating layers interposed therebetween. It should be noted that the number of vias 222, the number of conductive traces 224 and the number of insulating layers 226 shown in FIG. 5 are only an example and is not a limitation to the present disclosure.

In some embodiments, the redistribution layers 220-1 and 220-2 are connected to (or coupled to) the conductive material 204 in the holes TH1 and TH2. More specifically, the conductive material 204 in the holes TH1 and TH2 may be connected to the conductive layers 208-1 and 208-2. The conductive layers 208-1 and 208-2 may be connected to the corresponding vias 222 in the insulating layers 226 of the redistribution layers 220-1 and 220-2.

In some embodiments, the insulating layers 226 in the redistribution layers 220-1 and 220-2 include a low-k dielectric material. The dielectric constant of the insulating layers 226 may be between about 3 and 4, which is less than the dielectric constant of the of the high-k dielectric material 306.

In the semiconductor structure 500C, the conductive material 204 in the holes TH1 and TH2 and the high-k dielectric material 306 in the hole TH3 may form a capacitor CA3 embedded in the substrate 200C. Therefore, the semiconductor structure 500C has a plurality of capacitors CA3 formed embedded in the substrate 200C. In each of the capacitors CA3, the conductive material portion 204-1 lining the inner wall of the hole TH1 may serve as a first electrode 204-1 of the capacitor CA3, and the conductive material portion 204-2 lining the inner wall of the hole TH2 may serve as a second electrode 204-2 of the capacitor CA3. The high-k dielectric material 306 disposed in the hole TH3 and a portion of core 202 located between the first electrode 204-1 and the second electrode 204-2 may serve as a dielectric material of the capacitor CA3. In some embodiments, the first electrode 204-1 (or the second electrode 204-2) is commonly used by the adjacent two capacitors CA3.

In some embodiments, the conductive material portions 204-1 lining the inner walls of the different holes TH1 are connected (coupled) each other by the vias 222 and the conductive traces 224 in the redistribution layer 220-1 and/or the vias 222 and the conductive traces 224 in the redistribution layer 220-2. In addition, the conductive material portions 204-2 lining the inner walls of the different holes TH2 are connected each other by the vias 222 and the conductive traces 224 in the redistribution layer 220-1 and/or the vias 222 and the conductive traces 224 in the redistribution layer 220-2. In some embodiments, the vias 222 and the conductive traces 224 in the redistribution layer 220-1 and/or the redistribution layer 220-2 connected (coupled) to the first electrodes 204-1 (the conductive material portions 204-1) are separated from the vias 222 and the conductive traces 224 in the redistribution layer 220-1 and/or the redistribution layer 220-2 connected (coupled) to the second electrodes 204-2 (the conductive material portions 204-2). That is, there is no electrical connection between the vias 222 and the conductive traces 224 in the redistribution layer 220-1 and/or the redistribution layer 220-2 connected (coupled) to the first electrodes 204-1 (the conductive material portions 204-1) and the vias 222 and the conductive traces 224 in the redistribution layer 220-1 and/or the redistribution layer 220-2 connected (coupled) to the second electrodes 204-2 (the conductive material portions 204-2).

According to the connections of the first electrodes 204-1 (the conductive material portions 204-1) and the connections of the second electrodes 204-2 (the conductive material portions 204-2), the capacitors CA3 formed in the same substrate 200C are connected in parallel. The semiconductor structure 500C may have a large capacitance.

In the semiconductor structure 500C, the capacitors CA3 may be formed inside the substrate 200C using the processes for forming the substrate 200C. The capacitors CA3 may be formed integrated with the substrate 200C of the semiconductor structure 500C. The fabrication cost can be further reduced. The semiconductor structure 500C may use the thin conductive layer (i.e., the conductive material portions 204-1, 204-2) lining the holes TH1 and TH2 as the electrode plates of the capacitor CA3. In addition, the semiconductor structure 500A may use the high-k dielectric material 306 (the dielectric constant of the high-k dielectric material 306 is between about 10 and 20, such as ceramic) to fill the hole TH3 between the holes TH1 and TH2 as the dielectric material of the each of the capacitors CA3. The first electrode 204-1 and the second electrode 204-2 of capacitors CA3 may be formed passing through the core 202 in a direction that is vertical to the top surface 202T and the bottom surface 202B of the core 202. The capacitance of each of the capacitors CA3 can be increased. Furthermore, the capacitors CA3 formed in the same substrate 200C may be in a parallel connection to further increase the total capacitance. The semiconductor structure 500C integrating the package substrate (the substrate 200C) and large capacitance embedded capacitors CA3 are cost-effective and suitable for high-frequency applications.

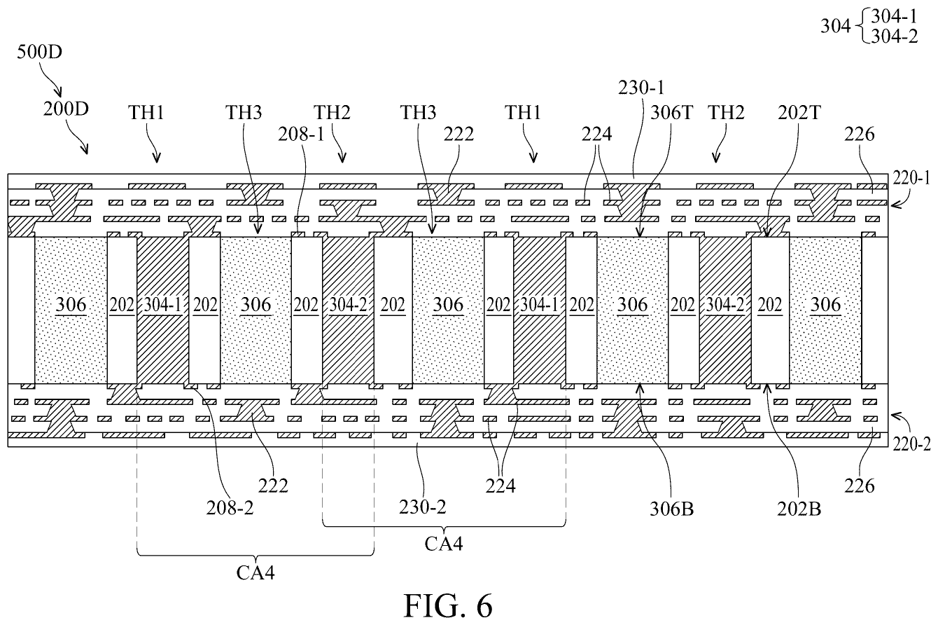

FIG. 6 is a schematic cross-sectional view of a semiconductor structure 500D in accordance with some embodiments of the disclosure. FIG. 4 is also a schematic top view of the semiconductor structure 500D of FIG. 6 in accordance with some embodiments of the disclosure, showing the arrangements of electrodes and dielectric material of a capacitor embedded in a substrate. Elements of the embodiments hereinafter, that are the same or similar as those previously described with reference to FIGS. 1 to 5, are not repeated for brevity.

As shown in FIGS. 2, 4, 5 and 6, the difference between the semiconductor structure 500C and the semiconductor structure 500D at least includes that a substrate 200D of the semiconductor structure 500D includes the conductive material 304 (including conductive material portions 304-1, 304-2) is formed as a conductive pillar filled in the holes TH1 and TH2.

The conductive material 304 in the hole TH1 (e.g., the conductive material portion 304-1) and the conductive material 304 in the hole TH2 (e.g., the conductive material portion 304-2) may have a pillar shape. Two terminals (not shown) of the conductive material 304 in each of the holes TH1 and TH2 may be close to the top surface 202T and the bottom surface 202B of the core 202, respectively. In addition, the two terminals of the conductive material 304 in each of the holes TH1 and TH2 may be exposed from the top surface 202T and the bottom surface 202B of the core 202, respectively.

In the semiconductor structure 500D, the conductive material 304 filling in the holes TH1 and TH2 and the high-k dielectric material 306 in the hole TH3 may form a capacitor CA4 embedded in the substrate 200D. Therefore, the semiconductor structure 500D has a plurality of capacitors CA4 formed embedded in the substrate 200D. In each of the capacitors CA4, the conductive material portion 304-1 filling the hole TH1 may serve as a first electrode 304-1 of the capacitor CA4, and the conductive material portion 304-2 filling the hole TH2 may serve as a second electrode 304-2 of the capacitor CA4. The high-k dielectric material 306 disposed in the hole TH3 and a portion of core 202 located between the first electrode 304-1 and the second electrode 304-2 may serve as a dielectric material of the capacitor CA4. In some embodiments, the first electrode 304-1 (or the second electrode 304-2) is commonly used by the adjacent two capacitors CA4.

In some embodiments, the conductive material portions 304-1 filling the different holes TH1 are connected (coupled) each other by the vias 222 and the conductive traces 224 in the redistribution layer 220-1 and/or the vias 222 and the conductive traces 224 in the redistribution layer 220-2. In addition, the conductive material portions 304-2 filling the different holes TH2 are connected each other by the vias 222 and the conductive traces 224 in the redistribution layer 220-1 and/or the vias 222 and the conductive traces 224 in the redistribution layer 220-2. In some embodiments, the vias 222 and the conductive traces 224 in the redistribution layer 220-1 and/or the redistribution layer 220-2 connected (coupled) to the first electrodes 304-1 (the conductive material portions 304-1) are separated from the vias 222 and the conductive traces 224 in the redistribution layer 220-1 and/or the redistribution layer 220-2 connected (coupled) to the second electrodes 304-2 (the conductive material portions 304-2). That is, there is no electrical connection between the vias 222 and the conductive traces 224 in the redistribution layer 220-1 and/or the redistribution layer 220-2 connected (coupled) to the first electrodes 304-1 (the conductive material portions 304-1) and the vias 222 and the conductive traces 224 in the redistribution layer 220-1 and/or the redistribution layer 220-2 connected (coupled) to the second electrodes 304-2 (the conductive material portions 304-2).

According to the connections of the first electrodes 304-1 (the conductive material portions 304-1) and the connections of the second electrodes 304-2 (the conductive material portions 304-2), the capacitors CA4 formed in the same substrate 200D are connected in parallel. The semiconductor structure 500D may have a large capacitance.

In the semiconductor structure 500D, the capacitors CA4 may be formed inside the substrate 200D using the processes for forming the substrate 200D. The capacitor CA4 may be formed integrated with the substrate 200D of the semiconductor structure 500D. The fabrication cost can be further reduced. The semiconductor structure 500D may use the conductive pillars (i.e., the conductive material portions 304-1, 304-2) filling the holes TH1 and TH2 as the electrodes of each of the capacitor CA4. In addition, the semiconductor structure 500D may use the high-k dielectric material 306 (the dielectric constant of the high-k dielectric material 306 is between about 10 and 20, such as ceramic) to fill the hole TH3 between the holes TH1 and TH2 as the dielectric material of the each of the capacitors CA4. The first electrode 304-1 and the second electrode 304-2 of capacitors CA4 may be formed passing through the core 202 in a direction that is vertical to the top surface 202T and the bottom surface 202B of the core 202. The capacitance of each of the capacitors CA4 can be increased. Furthermore, the capacitors CA4 formed in the same substrate 200D may be in a parallel connection to further increase the total capacitance. The semiconductor structure 500D integrating the package substrate (the substrate 200D) and large capacitance embedded capacitors CA4 are cost-effective and suitable for high-frequency applications.

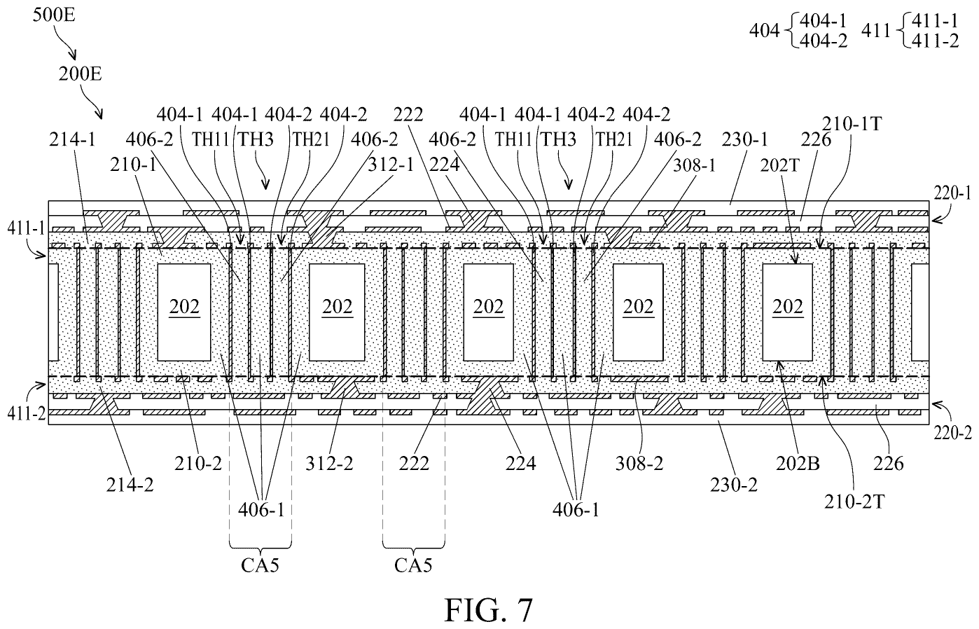

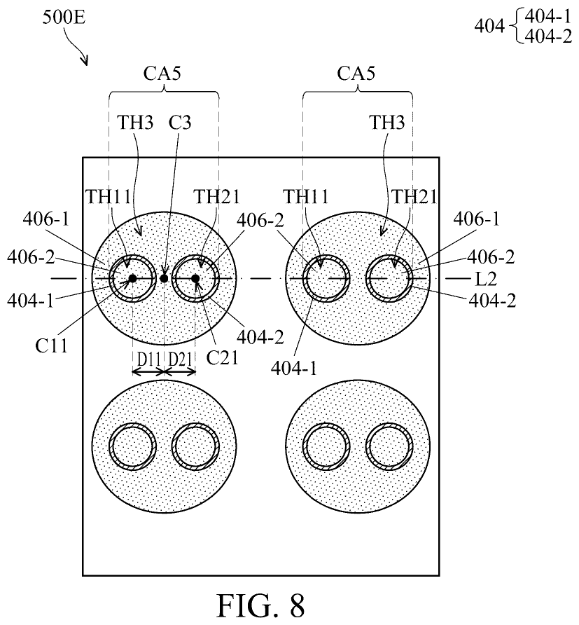

FIG. 7 is a schematic cross-sectional view of a semiconductor structure 500E in accordance with some embodiments of the disclosure. FIG. 8 is a schematic top view of a core 202 of the semiconductor structure 500E of FIG. 7 in accordance with some embodiments of the disclosure, showing the arrangements of electrodes and dielectric material of a capacitor embedded in a substrate. Elements of the embodiments hereinafter, that are the same or similar as those previously described with reference to FIGS. 1 to 6, are not repeated for brevity.

The semiconductor structure 500E includes a substrate 200E. In some embodiments, the substrate 200E includes the core 202, a conductive material 404, a high-k dielectric material 406 (including high-k dielectric materials 406-1 and 406-2), conductive layers 308-1 and 308-2, insulating layers 210-1, 210-2, 214-1 and 214-2, the redistribution layers 220-1 and 220-2, and the solder mask layers 230-1 and 230-2.

As shown in FIG. 7, the core 202 has holes TH11, TH21 and TH3 embedded it. In some embodiments, the holes TH11, TH21 and TH3 may be arranged repeatedly in a specific order. In some embodiments, the holes TH3 may be arranged as an array passing through the core 202, as shown in FIG. 7. The arrangements of the holes TH11 and TH21 will be described later.

The high-k dielectric material 406-1 is disposed in the hole TH3. As shown in FIGS. 1 and 2, the high-k dielectric material 406-1 may fill the hole TH3. In addition, the high-k dielectric material 406-1 may be in contact with an inner wall of the hole TH3. That is to say, the high-k dielectric material 406-1 may be in contact with the core 202.

In some embodiments, the dielectric constant of the high-k dielectric material 406-1 may be higher than the dielectric constant of the core 202. For example, the dielectric constant of the high-k dielectric material 406-1 is between about 10 and 20. In this embodiment, the high-k dielectric material 406-1 includes Ajinomoto Build-Up Film (ABF). In this embodiment, the high-k dielectric material 206 may be formed by coating or lamination.

As shown in FIG. 7, the insulating layers 210-1 and 210-2 of the semiconductor structure 500E are formed on the top surface 202T and the bottom surface 202B of the core 202, respectively. In addition, the insulating layers 210-1 and 210-2 may be disposed on the top and bottom of high-k dielectric material 406-1, respectively. In addition, the insulating layers 210-1 and 210-2 may cover the holes TH3.

In this embodiment, the holes TH11 and TH21 are formed passing through the high-k dielectric material 406-1 and separated from each other. In other words, the holes TH11 and TH21 are surrounded by the hole TH3. The holes TH11 and TH21 are formed passing through the high-k dielectric material 406-1. In addition, the holes TH11 and TH21 may extend into and penetrate the insulating layers 210-1 and 210-2.

In some embodiments, the center point C3 of the hole TH3 may be located on the line (e.g., a line L2) connecting the center point C11 of the hole TH11 with the center point C21 of the hole TH21. In some embodiments, the center point C3 of the hole TH3 may be located at the midpoint between the adjacent holes TH11 and TH21. In some embodiments, the distance D11 between the center point C3 of the hole TH3 to the center point C11 of the hole TH11 may be equal to or not equal to the distance D21 between the center point C3 of the hole TH3 to the center point C21 of the hole TH21. In some embodiments, the holes TH11, TH21 and TH3 may be formed by a drilling process.

The conductive material 404 (including conductive material portions 404-1, 404-2) is disposed in the hole TH11 and the hole TH21. In some embodiments as shown in FIGS. 7 and 8, each of the conductive material portions 404-1, 404-2 may be formed as a thin conductive layer lining inner walls of the hole TH11 and the hole TH21. The conductive material 404 in the hole TH11 (e.g., the conductive material portion 404-1) and the conductive material 404 in the hole TH21 (e.g., the conductive material portion 404-2) may have a hollow pillar shape. Two terminals (not shown) of the conductive material 404 in each of the holes TH11 and TH21 may be close to an outer surface 210-1T of the insulating layer 210-1 and an outer surface 210-2T of the insulating layer 210-2, respectively. In addition, the two terminals of the conductive material 404 in each of the holes TH11 and TH21 may be exposed from the outer surface 210-1T of the insulating layer 210-1 and the outer surface 210-2T of the insulating layer 210-2, respectively. In some embodiments, the conductive material 204 and 404 may include the same material, such as copper or nickel-copper.

As shown in FIGS. 7 and 8, the high-k dielectric material 406-2 may fill the remaining spaces of the holes TH11 and TH21 disposed in the third hole TH3 and surrounded by the conductive material 404. The high-k dielectric material 406-2 may be formed passing through the high-k dielectric material 406-1 and the insulating layers 210-1 and 210-2. The high-k dielectric material 406-2 in the holes TH11 and TH21 may be further surrounded by the high-k dielectric material 406-1. In the hole TH3, the high-k dielectric material 406-2 may be separated from the high-k dielectric material 406-1 by the conductive material 404. In some embodiments, the high-k dielectric materials 406-1 and 406-2 may include the same material, such as ABF.

Alternatively, the semiconductor structure 500E may use a low-k dielectric material (not shown) fill the remaining spaces of the holes TH11 and TH21 disposed in the third hole TH3 and surrounded by the conductive material 404. Therefore, the inner walls of the conductive material 404 may be in contact with the low-k dielectric material, and the outer walls of the conductive material 404 may be in contact with the high-k dielectric material 406-1.

In some embodiments, the high-k dielectric material 406-1 and the insulating layers 210-1 and 210-2 are formed of the same material (e.g., a high-k dielectric material having a dielectric constant of between about 10 and 20). In some embodiments, the high-k dielectric material 406-1 and the insulating layers 210-1 and 210-2 may be formed simultaneously using the same process. In this embodiment, the high-k dielectric materials 406-1 and the insulating layers 210-1 and 210-2 are formed as a high-k dielectric integrated structure 411-1. The high-k dielectric material 406-1 and the insulating layers 210-1 and 210-2 are different portions of the high-k dielectric integrated structure 411-1. There is no interface between high-k dielectric material 406-1 and the insulating layers 210-1 and 210-2. As shown in FIG. 7, the high-k dielectric integrated structure 411-1 may pass through the hole TH3 and extend to cover the top surface 202T and the bottom surface 202B of the core 202, respectively.

In this embodiment, the high-k dielectric integrated structure 411-1 may surround the holes TH11 and TH21, the conductive material 404 lining the inner walls of the holes TH11 and TH21 and the high-k dielectric material 406-2 filling the holes TH11 and TH21. In this embodiment, the high-k dielectric materials 406-1, 406-2 and the insulating layers 210-1 and 210-2 includes a high-k dielectric material suitable formed by coating or lamination, such as Ajinomoto Build-Up Film (ABF).

The conductive layers 308-1 and 308-2 are formed on the outer surfaces 210-1T and 210-2T of the insulating layers 210-1 and 210-2, respectively. In some embodiments, the conductive layers 308-1 and 308-2 may be connected to the conductive material 404 lining the inner walls of the holes TH11 and TH21. The conductive layers 308-1 and 308-2 may partially overlap the holes TH11, TH21 and TH3 and the high-k dielectric material 406-1 filling the hole TH3.

As shown in FIG. 7, the conductive layers 308-1 and 308-2 may partially cover the outer surfaces 210-1T and 210-2T of the insulating layers 210-1 and 210-2. In some embodiments, the top and bottom surface the high-k dielectric material 406-2 are not covered by the conductive layers 308-1 and 308-2.

In some embodiments, the conductive layers 308-1 and 308-2 may include a set of conductive traces or conductive planes. In some embodiments, the conductive layers 208-1, 208-2, 308-1 and 308-2 may include the same materials.

The insulating layers 214-1 and 214-2 are formed on the outer surfaces 210-1T and 210-2T of the insulating layers 210-1 and 210-2, respectively. In addition, the insulating layers 214-1 and 214-2 may be disposed on the conductive layers 308-1 and 308-2, respectively. In addition, the insulating layers 214-1 and 214-2 may cover the conductive layers 308-1 and 308-2, the holes TH11 and TH21, the conductive material 404 lining the inner walls of the holes TH11 and TH21 and the high-k dielectric material 406-2 filling the holes TH1 and TH2.

In some embodiments, the high-k dielectric material 406-2 and the insulating layers 214-1 and 214-2 are formed of the same material (e.g., a high-k dielectric material having a dielectric constant of between about 10 and 20). In some embodiments, the high-k dielectric material 406-2 and the insulating layers 214-1 and 214-2 may be formed simultaneously using the same process. In this embodiment, the high-k dielectric material 406-2 and the insulating layers 214-1 and 214-2 are formed as a high-k dielectric integrated structure 411-2. The high-k dielectric material 406-2 and the insulating layers 214-1 and 214-2 are different portions of the high-k dielectric integrated structure 411-2. There is no interface between the high-k dielectric material 406-1 and the insulating layers 210-1 and 210-2. As shown in FIG. 7, the high-k dielectric integrated structure 411-2 may be formed passing through the holes TH11 and TH21 and extend to cover the outer surfaces 210-1T and 210-2T of the insulating layers 210-1 and 210-2, respectively. In this embodiment, the high-k dielectric materials 406-2 and the insulating layers 210-1 and 210-2 includes a high-k dielectric material suitable formed by coating or lamination, such as Ajinomoto Build-Up Film (ABF).

In this embodiment, the high-k dielectric material 406-1, 406-2 and the insulating layers 210-1, 210-2, 214-1 and 214-2 are formed of the same material (e.g., a high-k dielectric material having a dielectric constant of between about 10 and 20). Therefore, the high-k dielectric integrated structure 411-1 and 411-2 may formed as a high-k dielectric composite structure 411.

As shown in FIG. 7, the semiconductor structure 500E further includes vias 312-1 and 312-2 disposed in the insulating layers 214-1 and 214-2. The vias 312-1 and 312-2 may be formed passing through the insulating layers 214-1 and 214-2 to be coupled to the conductive layers 308-1 and 308-2. For example, the vias 312-1 passing through the insulating layer 214-1 are coupled to portions of the conductive layer 308-1. Similarly, the vias 312-2 passing through the insulating layer 210-2 are coupled to portions of the conductive layer 308-2. The vias 312-1 and 312-2 may be formed without overlapping the high-k dielectric material 406-1 in the hole TH3 and the high-k dielectric material 406-2 in the holes TH11 and TH21. In some embodiments, the vias 312-1 and 312-2 may be formed by laser-drilling.

The redistribution layers (RDLs) 220-1 and 220-2 are disposed over the top surface 202T and the bottom surface 202B of the core 202. The redistribution layers 220-1 and 220-2 are disposed on the insulating layers 214-1 and 214-2, respectively. In some embodiments, each of the redistribution layers 220-1 and 220-2 includes one or more conductive traces 224, one or more vias 222 disposed in one or more insulating layers 226. It should be noted that the number of vias 222, the number of conductive traces 224 and the number of insulating layers 226 shown in FIG. 7 are only an example and is not a limitation to the present disclosure.

In some embodiments, the redistribution layers 220-1 and 220-2 are connected to (or coupled to) the conductive material 404 in the holes TH11 and TH21. More specifically, the conductive material 404 in the holes TH11 and TH21 may be connected to the conductive layers 308-1 and 308-2. The conductive layers 308-1 and 308-2 may be connected to the corresponding vias 312-1 and 312-2 in the insulating layers 214-1 and 214-2. The vias 312-1 and 312-2 located in the insulating layers 214-1 and 214-2 may be connected to vias or traces in the redistribution layers 220-1 and 220-2. For example, each of the conductive layer 308-1 and 308-2 include at least one of a first conductive plane or conductive trace connected to the conductive material 404-1 in the hole TH11 and the redistribution layer 220-1 and a second conductive plane or conductive trace connected to the conductive material 404-2 in the hole TH21 and the redistribution layer 220-2. The solder mask layers 230-1 and 230-2 may be disposed over the redistribution layers 220-1 and 220-2.

In the semiconductor structure 500E, the conductive material 204 in the holes TH11 and TH21 and the high-k dielectric material 406-1 in the hole TH3 and between the holes TH11 and TH21 may form a capacitor CA5 embedded in the substrate 200E. Therefore, the semiconductor structure 500E has a plurality of capacitors CA5 formed embedded in the substrate 200E. In each of the capacitors CA5, the conductive material portions 404-1 lining the inner walls of the hole TH11 may serve as a first electrode 404-1 of the capacitor CA5, and the conductive material portions 404-2 lining the inner walls of the hole TH21 may serve as a second electrode 404-2 of the capacitor CA5. The high-k dielectric material 406-1 disposed in the hole TH3 and located between the first electrode 404-1 and the second electrode 404-2 may serve as a dielectric material of the capacitor CA5. In some embodiments, each of the capacitors CA5 includes the individual first electrode 404-1 and the individual second electrode 404-2. In this embodiment, the dielectric material of the capacitor CA5 is only formed of the high-k dielectric material 406-1. The capacitor CA5 may have a capacitance higher than the capacitances of the capacitors CA1, CA2, CA3 and CA4.

In some embodiments, the conductive material portion 404-1 lining the inner wall walls of the different holes TH11 are connected (coupled) each other by the vias 312-1 in the insulating layer 214-1 and/or the vias 312-2 in the insulating layer 214-2. In addition, the conductive material portions 404-2 lining the inner wall walls of the different holes TH21 are connected each other by the vias 312-1 in the insulating layer 214-1 and/or the vias 312-2 in the insulating layer 214-2. In some embodiments, the vias 312-1 and/or the vias 312-2 connected (coupled) to the first electrodes 404-1 (the conductive material portions 404-1) are separated from the vias 312-1 and/or the vias 312-2 connected (coupled) to the second electrodes 404-2 (the conductive material portions 404-2). There is no electrical connection between the vias 312-1 and/or the vias 312-2 connected (coupled) to the first electrodes 404-1 (the conductive material portions 404-1) and the vias 312-1 and/or the vias 312-2 connected (coupled) to the second electrodes 404-2 (the conductive material portions 404-2).

In some embodiments, the conductive material portion 404-1 lining the inner wall walls of the different holes TH11 are connected (coupled) each other by the vias 312-1 in the insulating layer 214-1 and the vias 222 and the conductive traces 224 in the redistribution layer 220-1 and/or the vias 312-2 in the insulating layer 214-2 and the vias 222 and the conductive traces 224 in the redistribution layer 220-2. In addition, the conductive material portions 404-2 lining the inner wall walls of the different holes TH21 are connected each other by the vias 312-1 in the insulating layer 214-1 and the vias 222 and the conductive traces 224 in the redistribution layer 220-1 and/or the vias 312-2 in the insulating layer 214-2 and the vias 222 and the conductive traces 224 in the redistribution layer 220-2. In some embodiments, the vias 222 and the conductive traces 224 in the redistribution layer 220-1 and/or the redistribution layer 220-2 connected (coupled) to the first electrodes 404-1 (the conductive material portions 404-1) are separated from the vias 222 and the conductive traces 224 in the redistribution layer 220-1 and/or the redistribution layer 220-2 connected (coupled) to the second electrodes 404-2 (the conductive material portions 404-2). There is no electrical connection between the vias 222 and the conductive traces 224 in the redistribution layer 220-1 and/or the redistribution layer 220-2 connected (coupled) to the first electrodes 404-1 (the conductive material portions 404-1) and the vias 222 and the conductive traces 224 in the redistribution layer 220-1 and/or the redistribution layer 220-2 connected (coupled) to the second electrodes 404-2 (the conductive material portions 404-2).

In other words, the vias 312-1 in the insulating layer 214-1 and/or the vias 312-2 in the insulating layer 214-2 connected to the conductive material portion 404-1 in one hole TH11 may be connected to the conductive material portion 404-1 in another hole TH11 by the vias 222 and the conductive traces 224 in the redistribution layer 220-1 and/or the vias 222 and the conductive traces 224 in the redistribution layer 220-2. In addition, the vias 312-1 in the insulating layer 214-1 and/or the vias 312-2 in the insulating layer 214-2 connected to the conductive material portion 404-1 in one hole TH21 may be connected to the conductive material portion 404-1 in another hole TH21 by the vias 222 and the conductive traces 224 in the redistribution layer 220-1 and/or the vias 222 and the conductive traces 224 in the redistribution layer 220-2. In some embodiments, the vias 222 and the conductive traces 224 in the redistribution layer 220-1 and/or the redistribution layer 220-2 connected (coupled) to the first electrodes 404-1 (the conductive material portions 404-1) in the various holes TH11 are separated from the vias 222 and the conductive traces 224 in the redistribution layer 220-1 and/or the redistribution layer 220-2 connected (coupled) to the second electrodes 404-2 (the conductive material portions 404-2) in the various holes TH21.

According to the connections of the first electrodes 404-1 (the conductive material portions 404-1) and the connections of the second electrodes 404-2 (the conductive material portions 404-2), the capacitors CA5 formed in the same substrate 200E are connected in parallel. The semiconductor structure 500E may have a large capacitance.

In the semiconductor structure 500E, the capacitors CA5 may be formed inside the substrate 200E using the processes for forming the substrate 200E. The capacitor CA5 may be formed integrated with the substrate 200E of the semiconductor structure 500E. The fabrication cost can be further reduced. The semiconductor structure 500E may use the thin conductive layer lining the holes TH11 and TH21 as the electrode plates of each of the capacitors CA5. In addition, the semiconductor structure 500E may use the high-k dielectric material 406-1 (the dielectric constant of the high-k dielectric material 406-1 is between about 10 and 20, such as ABF) to fill the hole TH3 as the dielectric material of the each of the capacitors CA5. The first electrode 404-1 and the second electrode 404-2 of capacitors CA5 may be formed passing through the hole TH3 and the insulating layers 210-1 and 210-2 in a direction that is vertical to the top surface 202T and the bottom surface 202B of the core 202. The capacitance of each of the capacitors CA5 can be improved. Furthermore, the capacitors CA5 formed in the same substrate 200E may be in a parallel connection to further increase the total capacitance. The semiconductor structure 500E integrating the package substrate (the substrate 200E) and large capacitance embedded capacitors CA5 are cost-effective and suitable for high-frequency applications.

Embodiments provide a semiconductor structure. The semiconductor structure includes a substrate. The substrate includes a core, a conductive material, a high-k dielectric material and a redistribution layer. The core has a first hole, a second hole and a third hole passing through it. The conductive material is disposed in the first hole and the second hole. The conductive material disposed in the first hole acts as a first electrode of a capacitor, the conductive material disposed in the second hole acts as a second electrode of the capacitor. The high-k dielectric material is disposed in the third hole and between the first electrode and the second electrode. The high-k dielectric material acts as a dielectric material of the capacitor. The redistribution layer is disposed on the core and connected to at least one of the conductive material in the first hole and the conductive material in the second hole.

In some embodiments, a dielectric constant of the high-k dielectric material is higher than a dielectric constant of the core, and the dielectric constant of the high-k dielectric material is between 10 and 20.

In some embodiments, the high-k dielectric material comprises Ajinomoto Build-Up Film (ABF) or ceramic.

In some embodiments, the third hole is disposed between the first hole and the second hole, and the first hole and the second hole pass through the core.

In some embodiments, the first hole and the second hole are filled with the conductive material.

In some embodiments, inner walls of the first hole and the second hole are lined with the conductive material.

In some embodiments, the semiconductor structure further includes a non-conductive material filled in the first hole and the second hole and surrounded by the conductive material, wherein the non-conductive material comprises an ink.

In some embodiments, the semiconductor structure further includes a conductive layer including a conductive plane or a conductive trace formed on a surface of the core and disposed between the core and the redistribution layer. The conductive layer includes at least one of a first conductive plane or conductive trace connected to the conductive material in the first hole and the redistribution layer and a second conductive plane or conductive trace connected to the conductive material in the second hole and the redistribution layer.

In some embodiments, the semiconductor structure further includes an insulating layer formed on the core and disposed between the core and the redistribution layer. The insulating layer and the high-k dielectric material are formed of the same material, and the insulating layer covers the first hole, the second hole and the third hole.

In some embodiments, the semiconductor structure further includes a first via and a second via. The first via is disposed in the insulating layer and connected to the conductive material in the first hole and a first trace in the redistribution layer disposed on the insulating layer. The second via is disposed in the insulating layer and connected to the conductive material in the second hole and a second trace in the redistribution layer. The first trace and the second trace are separated from each other.

In some embodiments, the semiconductor structure further includes a conductive layer including a conductive plane or a conductive trace formed on the surface of the core and disposed between the insulating layer and the redistribution layer, wherein the conductive layer comprises at least one of a first conductive plane or conductive trace connected to the conductive material in the first hole and the first via and a second conductive plane or conductive trace connected to the conductive material in the second hole and the second via.

In some embodiments, the first hole and the second hole are disposed in the third hole.

In some embodiments, the first hole and the second hole are disposed to pass through the third hole.

In some embodiments, the semiconductor structure further includes a first insulating layer formed on the core and between the core and the redistribution layer. The insulating layer and the high-k dielectric material are formed of the same material, and the insulating layer covers the third hole, wherein the first hole and the second hole extend into and penetrate the insulating layer.

In some embodiments, the semiconductor structure further includes a first set of conductive planes or conductive traces, and a second insulating layer. The first set of conductive planes or conductive traces is formed on the first insulating layer. The second insulating layer is disposed on the first set of conductive planes or conductive traces and the first insulating layer. The high-k dielectric material and at least one of the first insulating layer and the second insulating layer are formed of the same material.

In some embodiments, the first set of conductive planes or conductive traces includes at least one of a first conductive plane or conductive trace connected to the conductive material disposed in the first hole and a second conductive plane or conductive trace connected to the conductive material disposed in the second hole. The semiconductor structure further includes at least one of a first via and a second via. The first via disposed in the first insulating layer and connected to the first conductive plane or conductive trace and a first conductive trace in the redistribution layer disposed on the insulating layer. The second via disposed in the first insulating layer and connected to the second conductive plane or conductive trace and a second trace in the redistribution layer, wherein the first trace and the second trace are separated from each other.

In some embodiments, inner walls of the first hole and the second hole are lined with the conductive material, a non-conductive material is filled in the first hole and the second hole and surrounded by the conductive material, and the non-conductive material and the second insulating layer are formed of the same material.

Embodiments provide a semiconductor structure. The semiconductor structure includes a substrate and a capacitor embedded in the substrate. The substrate includes a core, a first insulating layer and a second insulating layer. The core has a first hole, a second hole and a third hole passing through it. The first insulating layer and a second insulating layer are disposed at opposite sides of the core. The capacitor includes a first electrode, a second electrode and a high-k dielectric material. The first electrode is formed by a conductive material disposed in the first hole. The second electrode is formed by the conductive material disposed in the second hole. The high-k dielectric material is disposed at least in the third hole and between the first electrode and the second electrode. The dielectric constant of the high-k dielectric material is between 10 and 20.

In some embodiments, the first hole and the second hole are disposed in the third hole, pass through the third hole and filled with the high-k dielectric material.

In some embodiments, the first hole and the second hole extend into and penetrate the first insulating layer and the second insulating layer.

In some embodiments, the semiconductor structure further includes a first set of conductive planes or conductive traces, a second set of conductive planes or conductive traces, a third insulating layer, and a fourth insulating layer. The first set of conductive planes or conductive traces is formed on the first insulating layer. The second set of conductive planes or conductive traces is formed on the second insulating layer. The third insulating layer is disposed on the first set of conductive planes or conductive traces and the first insulating layer. The fourth insulating layer is disposed on the second set of conductive planes or conductive traces and the second insulating layer. The high-k dielectric material and at least one of the insulating layers (i.e. the first insulating layer, the second insulating layer, the third insulating layer, and the fourth insulating layer) are formed of the same material.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure comprising
a substrate, wherein the substrate comprises:
a core having a first hole, a second hole and a third hole passing through it;
a conductive material disposed in the first hole and the second hole, wherein the conductive material disposed in the first hole acts as a first electrode of a capacitor, the conductive material disposed in the second hole acts as a second electrode of the capacitor;
a high-k dielectric material disposed in the third hole and between the first electrode and the second electrode, wherein the high-k dielectric material acts as a dielectric material of the capacitor; and
a redistribution layer disposed on the core and connected to at least one of the conductive material in the first hole and the conductive material in the second hole.

2. The semiconductor structure as claimed in claim 1, wherein a dielectric constant of the high-k dielectric material is higher than a dielectric constant of the core, and the dielectric constant of the high-k dielectric material is between 10 and 20.

3. The semiconductor structure as claimed in claim 1, wherein the high-k dielectric material comprises Ajinomoto Build-Up Film (ABF) or ceramic.

4. The semiconductor structure as claimed in claim 1, wherein the third hole is disposed between the first hole and the second hole, and the first hole and the second hole pass through the core.

5. The semiconductor structure as claimed in claim 1, wherein the first hole and the second hole are filled with the conductive material.

6. The semiconductor structure as claimed in claim 1, wherein inner walls of the first hole and the second hole are lined with the conductive material.

7. The semiconductor structure as claimed in claim 6, further comprising:
a non-conductive material filled in the first hole and the second hole and surrounded by the conductive material, wherein the non-conductive material comprises an ink.

8. The semiconductor structure as claimed in claim 1, further comprising:
a conductive layer comprising a conductive plane or a conductive trace formed on a surface of the core and disposed between the core and the redistribution layer, wherein the conductive layer comprises at least one of a first conductive plane or conductive trace connected to the conductive material in the first hole and the redistribution layer and a second conductive plane or conductive trace connected to the conductive material in the second hole and the redistribution layer.

9. The semiconductor structure as claimed in claim 1, further comprising:
an insulating layer formed on the core and disposed between the core and the redistribution layer, wherein the insulating layer and the high-k dielectric material are formed of the same material, and the insulating layer covers the first hole, the second hole and the third hole.

10. The semiconductor structure as claimed in claim 9, further comprising:
at least one of a first via and a second via, wherein
the first via disposed in the insulating layer and connected to the conductive material in the first hole and a first trace in the redistribution layer disposed on the insulating layer; and
the second via disposed in the insulating layer and connected to the conductive material in the second hole and a second trace in the redistribution layer, wherein the first trace and the second trace are separated from each other.

11. The semiconductor structure as claimed in claim 10, further comprising:
a conductive layer comprising a conductive plane or a conductive trace formed on a surface of the core and disposed between the insulating layer and the redistribution layer, wherein the conductive layer comprises at least one of a first conductive plane or conductive trace connected to the conductive material in the first hole and the first via and a second conductive plane or conductive trace connected to the conductive material in the second hole and the second via.

12. The semiconductor structure as claimed in claim 1, wherein the first hole and the second hole are disposed in the third hole.

13. The semiconductor structure as claimed in claim 12, wherein the first hole and the second hole are disposed to pass through the third hole.

14. The semiconductor structure as claimed in claim 1, further comprising:
a first insulating layer formed on the core, wherein the first insulating layer and the high-k dielectric material are formed of the same material, and the first insulating layer covers the third hole, wherein the first hole and the second hole extend into and penetrate the first insulating layer.

15. The semiconductor structure as claimed in claim 14, further comprising:
a first set of conductive planes or conductive traces formed on the first insulating layer;
a second insulating layer disposed on the first set of conductive planes or conductive traces and the first insulating layer.

16. The semiconductor structure as claimed in claim 15, wherein
the first set of conductive planes or conductive traces comprises at least one of a first conductive plane or conductive trace connected to the conductive material disposed in the first hole and a second conductive plane or conductive trace connected to the conductive material disposed in the second hole; and
wherein the semiconductor structure further comprises at least one of a first via and a second via, wherein
the first via disposed in the first insulating layer and connected to the first conductive plane or conductive trace and a first conductive trace in the redistribution layer disposed on the insulating layer, and
the second via disposed in the first insulating layer and connected to the second conductive plane or conductive trace and a second trace in the redistribution layer, wherein the first trace and the second trace are separated from each other.

17. The semiconductor structure as claimed in claim 15, wherein inner walls of the first hole and the second hole are lined with the conductive material, a non-conductive material is filled in the first hole and the second hole and surrounded by the conductive material, and the non-conductive material and the second insulating layer are formed of the same material.

18. A semiconductor structure, comprising:
a substrate, wherein the substrate comprises:
a core having a first hole, a second hole and a third hole passing through it;
a first insulating layer and a second insulating layer disposed at opposite sides of the core; and
a capacitor embedded in the substrate, wherein the capacitor comprises:
a first electrode formed by a conductive material disposed in the first hole;
a second electrode formed by the conductive material disposed in the second hole;
a high-k dielectric material disposed at least in the third hole and between the first electrode and the second electrode, wherein the dielectric constant of the high-k dielectric material is between 10 and 20.

19. The semiconductor structure as claimed in claim 18, wherein the first hole and the second hole are disposed in the third hole, pass through the third hole and filled with the high-k dielectric material, and the first hole and the second hole penetrate the first insulating layer and the second insulating layer.

20. The semiconductor structure as claimed in claim 18, further comprising:
a first set of conductive planes or conductive traces formed on the first insulating layer;
a second set of conductive planes or conductive traces formed on the second insulating layer;
a third insulating layer disposed on the first set of conductive planes or conductive traces and the first insulating layer; and
a fourth insulating layer disposed on the second set of conductive planes or conductive traces and the second insulating layer,
wherein the high-k dielectric material and at least one of the first insulating layer, the second insulating layer, the third insulating layer, and the fourth insulating layer are formed of the same material, and the first set of conductive planes or conductive traces comprise a first conductive plane or conductive trace connected to the conductive material disposed in the first hole and a second conductive plane or conductive trace connected to the conductive material disposed in the second hole, or, the first set of conductive planes or conductive traces comprise a first conductive plane or conductive trace connected to the conductive material disposed in the first hole, and a second set of conductive planes or conductive traces comprise a second conductive plane or conductive trace connected to the conductive material disposed in the second hole.
